(19) United States
(12) Patent Application Publication
(10) Pub. No.: US 2010/0108137 A1
(43) Pub. Date: May 6, 2010

(54) CRYSTALLINE SOLAR CELL HAVING STACKED STRUCTURE AND METHOD OF MANUFACTURING THE CRYSTALLINE SOLAR CELL

(75) Inventor: Byoung-Su Lee, Yeosu-si (KR)

Correspondence Address: Jae Y. Park, Kile, Goekjian, Reed & McManus, PLLC, 1200 New Hampshire Ave. NW, Suite 570, Washington, DC, 20036, US

(73) Assignee: SILICONFILE TECHNOLOGIES INC., Seoul (KR)

(21) Appl. No.: 12/532,807

(22) PCT Filed: Apr. 4, 2008
(86) PCT No.: PCT/KR2008/001896

§ 371 Date: Sep. 23, 2009

(30) Foreign Application Priority Data
Apr. 5, 2007 (KR) 10-2007-0033634

(51) Int. Cl. H01L 31/00; H01L 31/18

(52) U.S. Cl. 136/256; 438/97; 257/E21.09

(57) ABSTRACT

Provided are a crystalline solar cell having a stacked structure capable of increasing light absorption efficiency and preventing deterioration in a semiconductor and a method of manufacturing the crystalline solar cell. The crystalline solar cell having a stacked structure includes a non-conductive lattice buffer layer which is made of a non-conductive material and formed between crystalline solar cell layers, wherein the non-conductive lattice buffer layer electrically connects the solar cell layers to each other by a tunneling effect. The method of manufacturing the crystalline solar cell includes steps of forming a crystalline first solar cell layer, forming a non-conductive lattice buffer layer using a non-conductive material on the first solar cell layer, and forming a crystalline second solar cell layer on the non-conductive lattice buffer layer.

### BACKGROUND OF THE INVENTION

1. Field of the Invention

The present invention relates to a solar cell, and more particularly, to a crystalline solar cell having a stacked structure with high light absorption efficiency.

2. Description of the Related Art

In general, it is well known that a solar cell having a stacked structure can absorb light in a very wide wavelength range and has high light absorption efficiency. For this, in the stacked structure of the solar cell, a solar cell layer having a wide band gap is disposed at a front surface on which light is incident and a solar cell layer having a narrow band gap is disposed at a rear surface on which the light incident later.

FIG. 1 illustrates a solar cell having a conventional stacked structure. The solar cell 100 having the conventional stacked structure illustrated in FIG. 1 includes a first solar cell layer 110a which has a wide band gap A and is disposed at a front surface in a direction 101 of incident light and a second solar cell layer 110b which has a narrow band gap B and is disposed at a rear surface in the direction 101 of incident light. In order to electrically connect the solar cell layers 110a and 110b having different band gaps, in general, a transparent conductive oxide (TCO) layer 120 which is transparent and conductive is disposed between the solar cell layers 110a and 110b.

Light incident on the solar cell 100 is first absorbed by the first solar cell layer 110a and light that the first solar cell layer 110a cannot absorb is absorbed by the second solar cell layer 110a having the narrow band gap B.

FIG. 2 illustrates an example of an energy band of the solar cell 100 illustrated in FIG. 1.

An electron e and a hole h which are generated at first and second solar cell layer 110a and 110b by incident light, respectively, are separated by potentials, and a recombination 201 of an electron e and a hole h generated at the first and second solar cell layer 110a and 110b, respectively, occurs at the TCO layer 120. In addition, due to the electron e and the hole h which are separated from each other to both ends, quasi Fermi levels at the both ends are different from each other, so that a voltage occurs.

Therefore, in the solar cell 100 having the stacked structure as illustrated in FIG. 1, light absorption occurs in a wider area as compared with a solar cell having a single solar cell layer, so that the solar cell 100 has an advantage of high light absorption efficiency.

In order to manufacture the solar cell having the stacked structure as illustrated in FIG. 1, stacked solar cell layers having different band gaps and different lattice parameters are needed.

However, in a case where crystal growth of materials having different lattice parameters is performed in order to stack the solar cell layers, lattice defects occur due to a difference between the lattice parameters of the two materials for forming two solar cell layers, respectively, at the interface between the solar cell layers, and the generated lattice defects may operate as a recombination center between electron-hole. This results in increase in a recombination rate and decrease in electricity generation efficiency. Therefore, in order to construct a solar cell having high efficiency, a lattice buffer layer for removing the lattice defects that occur between solar cell layers having different lattice parameters is needed. For this, in a conventional method of forming the lattice buffer layer, for example, when a solar cell having a stacked structure including a solar cell layer made of silicon (Si) having a band gap A of about 1.1 eV and a solar cell layer made of germanium (Ge) having a band gap B of about 0.7 eV is to be constructed, a Si₁₋ₓGeₓ (here, 0<x<1) layer having a lattice parameter that is changed according to a ratio of Ge is formed between the Si and Ge layers. Specifically, by changing the value x that is the ratio of Ge of the Si₁₋ₓGeₓ layer serving as the lattice buffer layer between the Si and Ge layers in a range of from 0 to 1, the lattice is controlled. However, the aforementioned method has complex processes and has a disadvantage in that lattice strain cannot be removed.

In an alternate method, as illustrated in FIG. 1, the solar cell layers 110a and 110b using amorphous semiconductors are stacked, and the TCO layer 120 is used as an intermediate lattice buffer layer.

However, since the TCO layer 120 is formed by an oxide and doped impurities, in a case where the TCO layer 120 is used for a crystalline solar cell having the stacked structure, the doped impurities may contaminate the crystalline solar cell layers in a crystalline growth process performed at a high temperature. Therefore, there is a problem in that the TCO layer 120 cannot be used for the crystalline solar cell. Therefore, although the method using the TCO layer 120 can be used for an amorphous solar cell, the method cannot be applied to the crystalline solar cell.

### SUMMARY OF THE INVENTION

The present invention provides a crystalline solar cell having a stacked structure including a non-conductive lattice buffer layer that can remove lattice defects that may occur at the interface between solar cell layers having different band gaps and different lattice parameters from each other and electrically connect the solar cell layers to each other, thereby increasing light absorption efficiency.

The present invention also provides a method of manufacturing a crystalline solar cell having a stacked structure capable of forming a non-conductive lattice buffer layer to increase light absorption efficiency and prevent deterioration in a semiconductor and performing crystal growth of a solar cell layer on an upper portion of the non-conductive lattice buffer layer by using the non-conductive lattice buffer layer as a seed layer to block the inflow of impurities to the solar cell layer due to a high temperature in the crystal growth process by the seed layer and prevent deterioration in the solar cell layer.

According to an aspect of the present invention, there is provided a crystalline solar cell having a stacked structure including a non-conductive lattice buffer layer which is made of a non-conductive material and formed between crystalline solar cell layers, wherein the non-conductive lattice buffer layer electrically connects the solar cell layers to each other by a tunneling effect.

According to another aspect of the present invention, there is provided a method of manufacturing a crystalline solar cell having a stacked structure, including steps of: forming a crystalline first solar cell layer; forming a non-conductive lattice buffer layer using a non-conductive material on the first solar cell layer; and forming a crystalline second solar cell layer on the non-conductive lattice buffer layer.

### BRIEF DESCRIPTION OF THE DRAWINGS

FIG. 1 illustrates a solar cell having a conventional stacked structure.

FIG. 2 illustrates an energy band of the solar cell illustrated in FIG. 1.

FIG. 3 illustrates a crystalline solar cell having a stacked structure according to an embodiment of the present invention.

FIG. 4 illustrates an energy band of the solar cell illustrated in FIG. 3.

FIG. 5 illustrates a method of manufacturing a crystalline solar cell having a stacked structure according to an embodiment of the present invention.

### DETAILED DESCRIPTION OF THE INVENTION

Hereinafter, exemplary embodiments of the present invention will be described in detail with reference to the attached drawings.

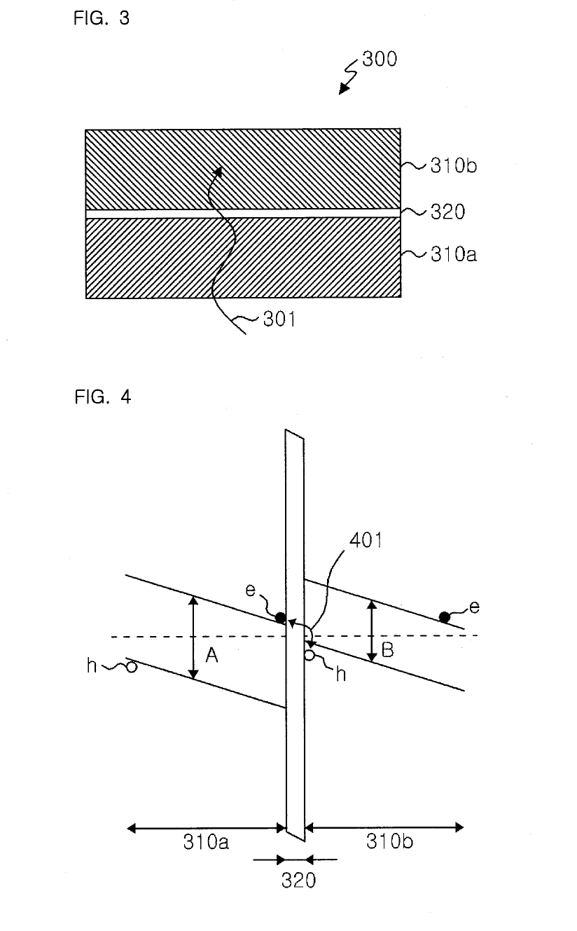

FIG. 3 illustrates a crystalline solar cell having a stacked structure according to an embodiment of the present invention. The crystalline solar cell 300 having a stacked structure illustrated in FIG. 3 includes a first solar cell layer 310a, a second solar cell layer 310b, and a non-conductive lattice buffer layer 320.

The crystalline first solar cell layer 310a is formed at a front surface in a direction 301 of incident light, and the crystalline second solar cell layer 310b is formed at a rear surface in the direction 301 of incident light. The non-conductive lattice buffer layer 320 is made of a non-conductive material and formed between the first and second solar cell layers 310a and 310b.

The first solar cell layer 310a first absorbs the incident light and may have a wide energy band of a relatively wider band gap A, and the second solar cell layer 310b absorbs light that passes through the first solar cell layer 310a and may have a narrow energy band of a relatively narrower band gap B than the first solar cell layer 310a.

For example, the first solar cell layer 310a may be made of silicon (Si) having a band gap A of about 1.1 eV, and the second solar cell layer 310b may be made of silicon-germanium (Si-Ge) having a band gap B of about from 0.7 eV to 1.1 eV. As a larger portion of the second solar cell layer 310b includes the Ge, the band gap decreases, and as a smaller portion of the second solar cell layer 310b includes the Ge, the band gap increases. A ratio of the Ge is determined according to a manufacturing purpose.

The non-conductive lattice buffer layer 320 electrically connects the first and second solar cell layers 310a and 310b to each other. When the non-conductive lattice buffer layer 320 is formed to have a small thickness of about from 1 nm to 20 nm, due to a tunneling effect, the first and second solar cell layers 310a and 310b can be electrically connected to each other.

The non-conductive lattice buffer layer 320 that is made of a non-conductive material may be an oxide or a nitride layer. Examples of the oxide layer include cerium dioxide (CeO₂), yttrium oxide (Y₂O₃), aluminum oxide (Al₂O₃), titanium oxide (TiO), strontium titanium oxide (SrTiO), zirconium silicon oxide (ZrSiO₄), tantalum oxide (Ta₂O₃), barium titanate (BaTiO₃), zirconium dioxide (ZrO₂), hafnium dioxide (HfO₂), and silicon dioxide (SiO₂), and examples of the nitride layer include silicon nitride (SiN), gallium nitride (GaN), titanium nitride (TiN), and aluminum nitride (AlN). And the non-conductive lattice buffer layer 320 has a crystalline structure.

FIG. 4 illustrates an energy band of the solar cell 300 illustrated in FIG. 3 in a case where the Si layer is used as the first solar cell layer 310a, the Si-Ge layer is used as the second solar cell layer 310b, and the SiN layer is used as the non-conductive lattice buffer layer 320.

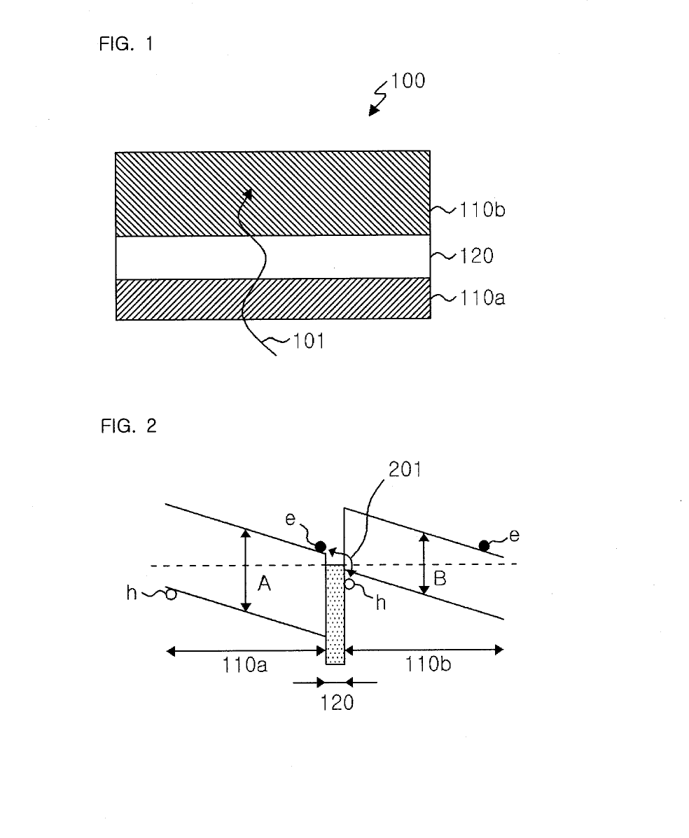

Referring to FIG. 4, a pair of electron-hole generated at the first solar cell layer 310a is separated from each other by a potential, and in this case, the electron e moves to the non-conductive lattice buffer layer 320, and the hole h moves to a surface of the first solar cell layer 310a. In addition, a hole h of a pair of electron-hole generated at the second solar cell layer 310b moves to the non-conductive lattice buffer layer 320, and the electron moves to a surface of the second solar cell layer 310b. When the non-conductive lattice buffer layer 320 has a thickness of about from 1 nm to 20 nm, among the electrons e and holes h generated at the solar cell layers 310a and 310b, the electron e and the hole h moved to the non-conductive lattice buffer layer 320 are recombined (denoted by 401) by a tunneling effect through the non-conductive lattice buffer layer 320. Therefore, the same effect as the case of using the conventional TCO layer (denoted by 120 in FIG. 1) can be achieved.

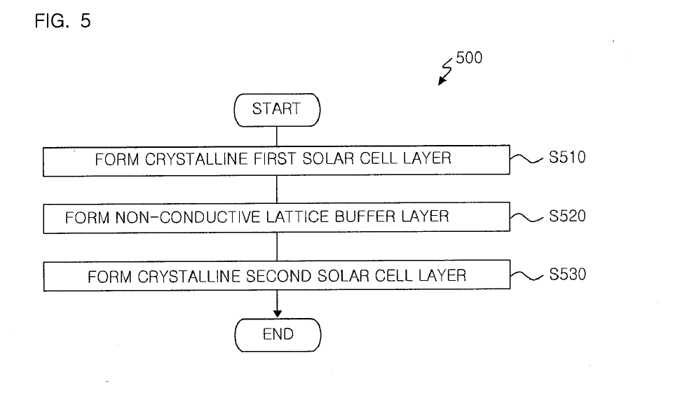

FIG. 5 illustrates a method of manufacturing a crystalline solar cell having a stacked structure according to an embodiment of the present invention.

The method 500 of manufacturing a crystalline solar cell having a stacked structure illustrated in FIG. 5 includes a step S510 of forming a first solar cell layer, a step S520 of forming a non-conductive lattice buffer layer, and a step S530 of forming a second solar cell layer. Hereinafter, for the convenience of description, numerals used to describe the elements in FIG. 3 are used.

In the step S510 of forming the first solar cell layer, the crystalline first solar cell layer 310a is formed. In the step S520 of forming the non-conductive lattice buffer layer, the non-conductive lattice buffer layer 320 is formed by using a non-conductive material, for example, an oxide layer such as CeO₂, Y₂O₃, Al₂O₃, TiO, SrTiO, ZrSiO₄, Ta₂O₃, BaTiO₃, ZrO₂, HfO₂, SiO₂, and the like or a nitride layer such as SiN, GaN, TiN, AlN, and the like, on the first solar cell layer 310a. Here, in the step S520 of forming the non-conductive lattice buffer layer, the non-conductive lattice buffer layer 320 is formed to have a thickness of about from 1 nm to 20 nm so as to be thinner than the first and second solar cell layers 310a and 310b so that the first and second solar cell layers 310a and 310b are electrically connected to each other by the tunneling effect.

In the step S530 of forming the second solar cell layer, the crystalline second solar cell layer 310b is formed on the non-conductive lattice buffer layer 320.

The first solar cell layer 310a formed in the step S510 of forming the first solar cell layer and the second solar cell layer 310b formed in the step S530 of forming the second solar cell layer are formed so that the first solar cell layer 310a disposed at the front surface in the direction 301 of incident light may have a wider energy band than the second solar cell layer 310b disposed at the rear surface in the direction 301 of incident light.

The first and second solar cell layers 310a and 310b have the crystalline structure, and the non-conductive lattice buffer layer 320 formed between the first and second solar cell layers 310a and 310b has to buffer a lattice difference between the first and second solar cell layers 310a and 310b. Therefore, an interatomic distance of a material used to form the non-conductive lattice buffer layer 320 in the step S520 of forming the non-conductive lattice buffer layer may have an intermediate value between interatomic distances of the first and second solar cell layers 310a and 310b. In addition, in the step S520 of forming the non-conductive lattice buffer layer, crystal growth of a non-conductive material may be performed to form the non-conductive lattice buffer layer 320.

For example, when the Si and the Ge are used for the first and second solar cell layers 310a and 310b, respectively, in the step S520 of forming the non-conductive lattice buffer layer, the SrTiO may be used for the non-conductive lattice buffer layer 320. Since an interatomic distance of the SrTio has an intermediate value between the Si and Ge, epitaxial growth of the SrTiO may be performed on the crystal-grown Si used as the first solar cell layer 310a, and crystal growth of the Ge layer used as the second solar cell layer 310b may be performed on the non-conductive lattice buffer layer 320. In this process, the SrTiO layer used as the non-conductive lattice buffer layer 320 serves as a seed layer for inducing crystal growth of the Ge in the process of crystallizing the Ge. In addition, since the oxide layer is thermally stable at a high temperature, the oxide layer prevents the solar cell layers and impurities from diffusing when the crystal growth of the Si is performed at a high temperature, so that deterioration in a semiconductor can be prevented.

The aforementioned stacked structure can be applied to a multi-layer structure using the same structure. Specifically, another non-conductive lattice buffer layer may be formed on the second solar cell layer 110b, and another third solar cell layer may be formed thereon, in order to form the multi-layer structure. As described above, the crystalline solar cell having the stacked structure uses the non-conductive lattice buffer layer having a wide band in order to solve defects due to a difference between lattice parameters of light absorption layers having different energy bands and different lattice parameters from each other, so that there are advantages in that lattice defects that may occur at the interface between the solar cell layers can be reduced, the number of recombinations between electrons-holes can be reduced, and light absorption efficiency can be increased.

In addition, the crystalline solar cell having the stacked structure does not use a transparent conductive oxide (TCO) layer having impurities, so that deterioration in a semiconductor that may occur due to a diffusion of the impurities at the TCO layer when the semiconductor crystal growth is performed can be avoided.

While the present invention has been particularly shown and described with reference to exemplary embodiments thereof, it will be understood by those skilled in the art that various changes in form and details may be made therein without departing from the spirit and scope of the present invention as defined by the appended claims.

1. A crystalline solar cell having a stacked structure comprising:
first and second crystalline solar cell layer: and
a non-conductive lattice buffer layer which is made of a non-conductive material to remove a lattice defect between the first and the second crystalline solar cell layers;
wherein the stacked structure is formed by epitaxially growing the non-conductive lattice buffer layer having a thickness smaller than that of the first or second crystalline solar cell layers on the first solar cell layer in order to electrically connects the first and second crystalline solar cell layers to each other by a tunneling effect, and performing crystal growth of the second solar cell layer on the non-conductive lattice buffer layer using the non-conductive lattice buffer layer as a seed layer.

2. The crystalline solar cell of claim 1, wherein the non-conductive lattice buffer layer is formed to have a thickness of from 1 nm to 20 nm.

3. The crystalline solar cell of claim 1, wherein the non-conductive lattice buffer layer is formed by an oxide layer or a nitride layer.

4. The crystalline solar cell of claim 1, wherein the non-conductive lattice buffer layer is formed by one selected from silicon dioxide (SiO₂), silicon nitride (SiN), cerium dioxide (CeO₂), yttrium oxide (Y₂O₃), aluminum oxide (Al₂O₃), titanium oxide (TiO), strontium titanium oxide (SrTiO), zirconium silicon oxide (ZrSiO₄), tantalum oxide (Ta₂O₃), barium titanate (BaTiO₃), zirconium dioxide (ZrO₂), gallium nitride (GaN), titanium nitride (TiN), aluminum nitride (AlN), and hafnium dioxide (HfO₂).

5. The crystalline solar cell of claim 1, wherein the non-conductive lattice buffer layer has a crystalline structure.

6. A method of manufacturing a crystalline solar cell by stacking first and crystalline cell layers, the method comprising:
performing crystal growth of the first crystalline solar cell layer;
epitaxially growing a non-conductive lattice buffer layer made of a non-conductive material on the first solar cell layer in order to remove a lattice defect between the first and second crystalline solar cell layers and electrically connects the first and second crystalline solar cell layers to each other by a tunneling effect, the non-conductive lattice buffer layer having a thickness smaller than that of the first or second crystalline solar cell layers; and
performing crystal growth of the second crystalline solar cell layer on the non-conductive lattice buffer layer while non-conductive lattice buffer layer is used to prevent diffusion of impurities.

7. (canceled)

8. The method of claim 6, wherein in the step of forming the non-conductive lattice buffer layer, the non-conductive lattice buffer layer is formed to have a thickness of from 1 nm to 20 nm.

9. The method of claim 6, wherein in the step of forming the non-conductive lattice buffer layer, the non-conductive lattice buffer layer is formed by an oxide layer or a nitride layer.

10. The method of claim 6, wherein in the step of forming the non-conductive lattice buffer layer, crystal growth of the non-conductive material is performed to form the non-conductive lattice buffer layer.

11. The method of claim 6, wherein in the step of forming the non-conductive lattice buffer layer, one selected from CeO₂, Y₂O₃, Al₂O₃, TiO, SrTiO, ZrSiO₄, Ta₂O₃, BaTiO₃, ZrO₂, GaN, TiN, AlN, and HfO₂ is used to form the non-conductive lattice buffer layer on the first solar cell layer.

12. The method of claim 11, wherein the selected one is used as a seed layer so as to be used for crystal growth of the second solar cell layer.
